(19) United States
(12) Patent Application Publication
(10) Pub. No.: US 2024/0220541 A1
(43) Pub. Date: Jul. 4, 2024

(54) FPGA-BASED METHOD AND SYSTEM FOR ACCELERATING GRAPH CONSTRUCTION

(71) Applicants: Huazhong University of Science and Technology, Wuhan City (CN); Zhejiang Lab, Hangzhou City (CN)

(72) Inventors: Long ZHENG, Wuhan City (CN); Chaoqiang LIU, Wuhan City (CN); Xiaofei LIAO, Wuhan City (CN); Hai JIN, Wuhan City (CN); Yu HUANG, Wuhan City (CN); Zhaozeng AN, Wuhan City (CN)

(21) Appl. No.: 18/497,233

(22) Filed: Oct. 30, 2023

(30) Foreign Application Priority Data
Dec. 30, 2022 (CN) 202211739018.4

(51) Int. Cl. G06F 16/901

(52) U.S. Cl. CPC G06F 16/9024

(57) ABSTRACT

An FPGA-based method and system for accelerating graph construction is provided, the method including: sampling neighborhood of each vertex in stored data and recording a traversal order of the vertices; according to the vertex traversal order, grouping the vertices into blocks and processing them by block-granularity, so as to at least obtain distance values between each two sampled neighbors of vertices in each block; according to the said distance values, updating neighborhoods of the two relevant vertices; and processing all of the blocks, starting a new iteration, until a satisfying precision or a predetermined limit of the number of iterations has been reached. The present disclosure utilizes the advantages of FPGA platform including flexibility, low power consumption and high parallelism, combined with the characteristics of graph construction algorithm, thereby greatly improving construction speed and reducing processing power consumption, so as to enable large-scale graph construction task processing in the datacenter.

### BACKGROUND OF THE APPLICATION

### 1. Technical Field

The present disclosure generally relates to high-performance computing, and more particularly to an FPGA-based method and system for accelerating graph construction.

### 2. Description of Related Art

Graphs represent a data structure extensively used in the real world as they can well describe complicated relations among entities, making them increasingly popular in modern computing systems. As machine learning is widely used, various types of data like texts, images, audios, and videos are often represented in the form of high-dimensional vectors. Thus, how to mine information of interest from these massive high-dimensional vectors has become a challenge. Currently, the most used solution is to convert these data into graphs, in which every vector is a vertex in the graph.

In a constructed graph structure, complicated data may be efficiently processed using many powerful graph-learning or graph-processing algorithms. The most popular graphic structure nowadays is k nearest neighbor (kNN) graphs. In such a graph, every node is connected to k nearest neighbors thereof. However, since vector data in real-world applications can have hundreds of dimensions and can be billions in data size, graph construction means huge random accesses and high-dimensional vector computing, making it time consuming and energy consuming. Hence, fast construction of a kNN graph for massive data with satisfying precision and low energy consumption is a challenging need to be addressed.

CN115374398A discloses a parallel hypergraph construction method based on FPGA. Therein, the computer system is configured to send a undirected adjacency matrix representing the generic graph to the FPGA; the FPGA is configured to receive and store the undirected adjacency matrix, generate an adjacency vertex set corresponding to each target vertex according to the undirected adjacency matrix, construct a hyper-edge corresponding to each target vertex according to the adjacency vertex set in parallel, and transmit all the hyper-edges to the computer system. The computer system receives all the hyper-edges sent by the FPGA and constructs a hyper-graph accordingly.

The existing approached to speeding up graph construction can be divided into two types. The first is about optimization at the level of graph construction algorithms, which reduces repeated computing during graph construction, and makes convergence happen faster by optimizing precision of the initial graph through introduction of new structures, like trees. Nevertheless, optimization at the level of algorithms has its limit and the increased speed is still not satisfying in practical use. The second type is hardware-based, such as an accelerating system based on a GPU. However, this solution has its shortcomings. First, a GPU platform usually has high power consumption, and when used in a datacenter for accelerating graph construction can lead to considerable energy consumption, making such a platform uneconomic for large-scale graph construction. Secondary, the small size of the cache on the GPU makes it difficult to make full use of potential locality among vertices during graph construction, and this limits the efficiency of graph construction. None of these known methods solves the problems related to huge accesses and computing overheads during graph construction.

FPGA platforms feature flexibility, low power consumption and high parallelism. Flexibility allows customize diverse parameter settings for graph construction algorithms on FPGAs. Low power consumption allows data centers where large-scale graph tasks are processed to save considerable costs. High parallelism contributes to significant improvement in efficiency of graph construction. Most importantly, it has not been seen in the art to accelerate graph construction with FPGAs.

As discussed above, the FPGA technology has been recognized as the most suitable platform for accelerating graph construction, yet there has not been a scheme that well combines the features of graph construction algorithms and advantages of an FPGA-based platform to accelerate construction of graphs. The objective of the present disclosure is to provide an FPGA-based method and system for accelerating graph construction.

Since there is certainly discrepancy between the existing art comprehended by the applicant of this patent application and that known by the patent examiners and since there are many details and disclosures disclosed in literatures and patent documents that have been referred by the applicant during creation of the present disclosure not exhaustively recited here, it is to be noted that the present disclosure shall actually include technical features of all of these existing works, and the applicant reserves the right to supplement the application with the related art more existing technical features as support according to relevant regulations.

### SUMMARY OF THE APPLICATION

In view of the shortcomings of the existing art, the present disclosure provides an FPGA-based method and system for accelerating graph construction, with the attempt to address at least one technical problem existing in the art.

To achieve the foregoing objective, the present disclosure provides an FPGA-based method for accelerating graph construction, comprising:
Step 1: sampling neighborhood of each vertex in stored data, respectively, and recording a traversal order for all of the vertices;
Step 2: according to vertex traversal order, grouping the vertices into a plurality of blocks and processing them by block granularity, so as to at least obtain distance values between each two sampled neighbors of each of the vertices in each of the blocks;
Step 3: according to the distance of the sampled neighbors of every vertex, updating the neighborhoods of the two vertices; and
Step 4: processing all of the blocks, starting a new iteration from Step 1, until a graph constructed therefrom has a satisfying precision or a predetermined limit of the number of iterations has been reached.

Preferably, in the present disclosure, Step 1 comprises steps of:
Step 11: sampling the neighborhood of each of the vertices, which includes adding IDs of some neighbors of the vertex into a sampling list, and adding the vertex's ID into a reverse list of the sampled neighbors, while recording a traversal order for all of the vertices during sampling; and
Step 12: repeating Step 11, until all of the vertices have been processed, and merging the sampling list and the reverse list of each of the vertices.

Preferably, in the present disclosure, Step 2 comprises steps of:
Step 21: loading the IDs of the sampled neighbors of all of the vertices in one of the blocks and feature vectors corresponding to these sampled neighbors; and
Step 22: computing data loaded in the Step 21 to acquire the distance values regarding the sampled neighbors of each of the vertices.

Preferably, in the present disclosure, Step 3 comprises steps of:
Step 31: reading a neighbor list of the two vertices to which each said distance value corresponds; and
Step 32: comparing each said distance value with distance values of existing neighbors of each vertex, so as to determine whether to add new neighbors to the neighbor list of the relevant vertex.

Preferably, Step 21 comprises steps of:
Step 211: according to the recorded IDs of all vertices in every block, reading data of the sampling lists of these vertices; and
Step 212: according to the data of the sampling lists of the vertices, reading the feature vectors of the sampled neighbors.

Preferably, Step 22 comprises steps of:
Step 221: according to loaded data of the sampled neighbors of each of the vertices and the feature vectors of these sampled neighbors, generating computing tasks; and
Step 222: processing the generated computing tasks, and recording a maximum distance value regarding each of the neighbors during computing, wherein when a computed intermediate result exceeds the maximum distance value, the relevant computing task is early terminated, and the intermediate result is discarded directly without participating in subsequent steps.

Preferably, the present disclosure relates to an FPGA-based system for accelerating graph construction, comprising a reading portion, a processing portion and an updating portion, which three all communicate with a DRAM.

The reading portion is used for reading a neighbor list of each of vertices in the DRAM and conducting sampling, wherein sampled data of each of the vertices are written back into the DRAM, and a traversal order of each of the vertices is recorded.

The processing portion is capable of, in response to the received vertex traversal order, grouping the vertices into a plurality of blocks and processing them by block granularity, so as to at least obtain distance values between each two sampled neighbors of each of the vertices in each of the blocks.

The updating portion is capable of, in response to the received distance values regarding the sampled neighbors of each of the vertices, reading the neighbor list of the two neighbors to which each said distance value corresponds from the DRAM, updating the neighbor lists of the two vertices, and writing the neighbor lists back into the DRAM.

Particularly, the disclosed system for accelerating graph construction processes all of the vertices in the DRAM by granularity of blocks. Since all the required vector data are prefetched to the chip from the blocks, the work load for accessing off-chip memories with high latency can be significantly decreased. Once the neighbor data of the vertices have been loaded, the system can immediately move these data to an idle processing module for processing, without waiting complete loading of all data of all neighborhoods in the blocks, so as to optimize efficiency throughout the dataflow.

Further, computing inside the processing modules of the system is executed in the dimension of vectors. The system caches the maximum similarity values of existing neighbors of every vertex pair inside the processing module. After processing all the dimensions of the vertex pair data, the processing module of the system compares the computed intermediate result with the maximum value. If the computing for the present vertex pair is recognized as unnecessary computing, the processing module directly ends the computing, and waits for subsequent processing. The intermediate result for which the computing is early terminated is not transferred to the updating module.

Preferably, the reading portion comprises one or more reading modules for processing vertex data in a CHANNEL in the DRAM, and the reading module comprises:
a neighbor reading sub-module, for generating addresses and reading the neighbor list of each of the vertices from the DRAM; and
a neighbor sampling sub-module, for receiving the neighbor list of each of the vertices in the DRAM, conducting sampling, and recording the traversal order of the vertices, wherein the neighbor sampling sub-module only samples some of the neighbors used in computing, and maintains a reverse neighbor list for each of the vertices, so as to merge the sampling list and the reverse neighbor list of each of the vertices when sampling finishes.

Preferably, the processing portion comprises:
a pre-reading module, for reading sampling data of all of vertices in the DRAM and vector data of the sampled neighbors, and on-chip caching the data; and
a distance computing module, capable of computing a distance value between each two of the sampled neighbors according to the sampling data and the vector data of all of the vertices from the pre-reading module.

Particularly, after the pre-reading module reads some vector data, the distance computing module can start execution. In addition, when the vector data of a block have been read, the pre-reading module can immediately start to read data of the next block, thereby hiding off-chip access delay and optimizing performance of the system.

Preferably, the pre-reading module may comprise one or more pre-reading sub-modules.

Further, the pre-reading sub-module may comprise:
a neighbor reading unit, for generating access addresses based on recorded IDs of the vertices in the blocks, and reading the sampled neighbors of these vertices from the DRAM; and
a neighbor sampling unit, for generating access addresses according to the vertex IDs of the sampled neighbors read from the neighbor reading unit, and reading vector data of the sampled neighbors from the DRAM.

Preferably, the distance computing module may comprise one or more distance computing sub-modules.

Further, the distance computing sub-module may comprise:
a vector caching unit, for acquiring vector data of the sampled neighbors of each of the vertices from the pre-reading module; and
a computing unit, for computing distance between vector data of each two of the sampled neighbors as cached in the vector caching unit, and sending the computing results to the updating portion.

Particularly, in the process of computing the distance between the sampled neighbors of each of the vertices based on the vector data of the sampled neighbors, the computing unit records the current maximum distance of the neighbors of every vertex. When the computed intermediate result exceeds the maximum distance, the relevant computing task is early terminated, and the computed result is discarded directly.

Preferably, the updating portion comprises one or more updating modules for processing the vertex data in a CHANNEL of the DRAM, and the updating module comprises:
a neighbor loading sub-module, for generating addresses and reading the neighbor list of each of the vertices from the DRAM; and
a neighbor merging sub-module, for receiving the distance values computed by the distance computing sub-module, reading the neighbor list of the two neighbors to which each said distance value corresponds from the DRAM, and comparing each said distance value with distance values of existing neighbors of each vertex, so as to determine whether to add new neighbors into the neighbor lists of the relevant vertices.

The present disclosure provides at least the following technical benefits. First, the disclosed FPGA-based method for accelerating graph construction arranges all vertices according to graininess of blocks, so it can make full use of locality among vertices, thereby reducing many random off-chip memory accesses. Meanwhile, the method saves computing time by terminating unnecessary computing timely. More importantly, the disclosed system and method for accelerating graph construction make full use of the advantages of an FPGA platform. Particularly, the inter-module dataflow hides off-chip memory access delay, and the use of multiple processing modules significantly enhances parallelism of the algorithms, thereby improving computing performance of the system.

### BRIEF DESCRIPTION OF THE DRAWINGS

FIG. 1 is a flowchart of an FPGA-based method for accelerating graph construction according to a preferred mode of the present disclosure;

FIG. 2 is a structural block diagram of an FPGA-based system for accelerating graph construction according to a preferred mode of the present disclosure; and

FIG. 3 is a structural diagram of an electronic device according to a preferred mode of the present disclosure.

### DETAILED DESCRIPTION OF THE APPLICATION

The present disclosure will be further detailed below with reference to accompanying drawings and particular embodiments.

### Embodiment 1

In order to solve the problems of the existing art about limited algorithm performance and high power consumption, the present disclosure provides an FPGA-based method and system for accelerating graph construction with the attempt to accelerate large-scale graph construction while maintaining low energy consumption overheads.

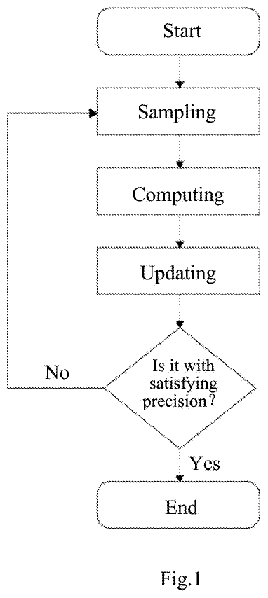

Specifically, referring to FIG. 1, the FPGA-based method for accelerating graph construction of the present disclosure may comprise the following steps:

Step 1: sampling neighborhood of each vertex in stored data, respectively, and recording a traversal order for all of the vertices;

Step 2: according to the vertex traversal order obtained in Step 1, grouping the vertices into a plurality of blocks, and processing them by granularity of blocks, so as to at least obtain distance values between each two sampled neighbors of each of the vertices in each of the blocks;

Step 3: according to the distance between two vertices obtained in Step 2, updating the neighborhoods of the two vertices; and

Step 4: processing all of the blocks, starting a new iteration from Step 1, until a graph constructed therefrom has a satisfying precision or a predetermined limit of the number of iterations has been reached.

According to a preferred mode, in Step 1, the apparatus/system for executing data collection or acquisition may be in communicative connection with an off-chip dynamic random access memory (DRAM), so as to be allowed to acquire data for executing graph construction from the off-chip DRAM, thereby being capable of sampling neighborhoods of all vertices in the data one by one, and recording a traversal order for all of the vertices.

According to a preferred mode, in Step 1, only a part of neighbor vertices of the vertices is allowed to participate in subsequent computing.

According to a preferred mode, in Step 2, each of the blocks is preferably a block of a fixed size.

According to a preferred mode, in Step 2, the step of obtaining the distance between the sampled neighbors of each of the vertices in every block may comprise: loading serial numbers of the sampled neighbors of all vertices in one block and feature vectors of these sampled neighbors at one time. By computing the loaded data, the distance between the sampled neighbors of each of the vertices can be obtained.

According to a preferred mode, in Step 3, according to the distance values regarding the sampled neighbors of each of the vertices, updating the neighborhoods of the two relevant vertices may be: receiving the distances between the sampled neighbors of every vertex, and reading a neighbor list of the two vertices to which each said distance value corresponds. Further, the distance value is compared with the distance values of the existing neighbors of each of the vertices, so as to determine whether to add new neighbors into the neighbor lists of the relevant vertices.

According to a preferred mode, in Step 4, as regards to the precision of the constructed graph, a predetermined limit of the number of iterations has been reached means, for example, iterating to a maximum number of rounds.

According to a preferred mode, in the present disclosure, Step 1 is achieved through the following sub-steps:
Step 11: sampling the neighborhood of each of the vertices, which includes adding IDs of some neighbor vertices of the vertex into a sampling list, and adding the vertex's ID into the reverse lists of the sampled neighbors, while recording a traversal order for all of the vertices during sampling; and
Step 12: repeating Step 11, until all of the vertices have been processed, and merging the sampling list and the reverse list of each of the vertices.

According to a preferred mode, in the present disclosure, Step 2 may be achieved through the following sub-steps:
Step 21: loading IDs of sampled neighbors of all vertices in a block and feature vectors corresponding to these sampled neighbors; and
Step 22: computing the distance between the sampled neighbors of each of the vertices by means of computing the loaded data.

According to a preferred mode, in the present disclosure, Step 21 may be achieved through the following sub-steps:
Step 211: according to the recorded IDs of the vertices in one or more blocks, reading the sampling list data of these vertices; and
Step 212: according to the read data of the sampling lists of the vertices, reading the feature vectors of the sampled neighbors.

According to a preferred mode, in the present disclosure, Step 22 may be achieved through the following sub-steps:
Step 221: according to the loaded sampled neighbor data of every vertex and the feature vectors of these sampled neighbors, generating computing tasks; and
Step 222: processing the generated computing tasks, and recording a maximum distance value regarding each of the neighbors during computing, wherein when a computed intermediate result exceeds the maximum distance value, the relevant computing task is early terminated, and the intermediate result is discarded directly without participating in subsequent steps.

According to a preferred mode, in the present disclosure, Step 3 is achieved through the following sub-steps:
Step 31: reading a neighbor list of the two vertices to which each said distance value corresponds; and
Step 32: comparing each said distance value with distance values of existing neighbors of each vertex, so as to determine whether to add new neighbors to the neighbor list of the relevant vertex.

In an optional mode, the disclosed FPGA-based method for accelerating graph construction may comprise:
Step 1: sampling neighborhoods of all vertices, and recording the traversal order of the vertices during sampling, wherein among all vertices only some neighbor vertices are allowed to participate in subsequent computing;
Step 2: according to the vertex traversal orders obtained in Step 1, grouping all vertices into blocks of a fixed size and processing them by granularity of blocks, wherein the IDs of the sampled neighbors of all vertices in a block and the feature vectors of these sampled neighbors are loaded at one time, and computing the distance between the sampled neighbors of each of the vertices by means of computing the loaded data.
Step 3: according to the distance between two vertices obtained in Step 2, updating the neighborhoods of the two vertices; and
Step 4: processing all of the blocks, starting a new iteration from Step 1, until a graph constructed therefore has a satisfying precision or a predetermined limit of the number of iterations has been reached.

Particularly, the disclosed method for accelerating graph construction may be used to construct indexes for image retrieval systems. Specifically, such an image retrieval system supports image search, meaning that it can search for identical or similar images in a designated image library, thereby suitable for precise image search, similar material search, photo-based product search, similar product recommendation or so on. Before search can be conducted, a graph index has to be constructed for all image data for minimizing search time. Therein, every image may be regarded as a vertex in a graph, and every image borders its k most similar images with edges. Therefore, a vertex neighborhood herein refers to k images most similar to the image of interest. This method can be used to speed up the index construction.

### Embodiment 2

The present embodiment provides an FPGA-based system for accelerating graph construction, which may be used to implement or execute an FPGA-based method for accelerating graph construction as described in Embodiment 1.

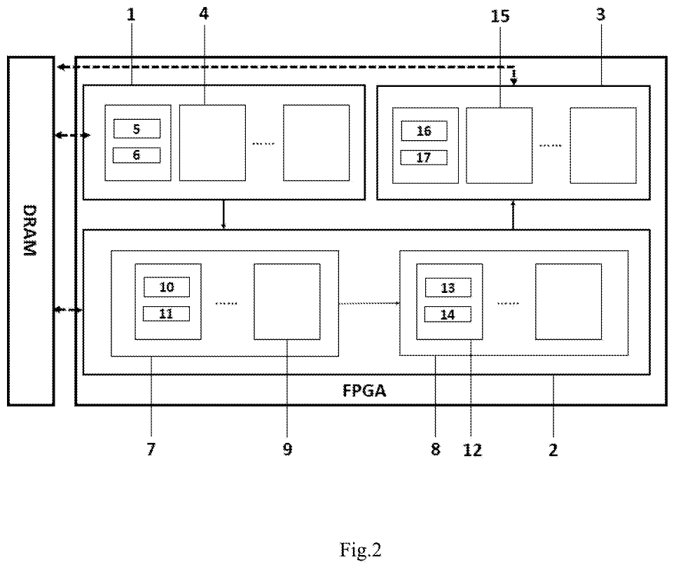

Specifically, referring to FIG. 2, the FPGA-based system for accelerating graph construction of the present embodiment may comprise a reading portion 1, a processing portion 2 and an updating portion 3, these three all communicating with each other. Further, the reading portion 1 may be in communicative connection with an off-chip dynamic random access memory (DRAM) and the processing portion 2, respectively. The processing portion 2 may be in communicative connection with an off-chip dynamic random access memory (DRAM), the reading portion 1 and the updating portion 3, respectively. The updating portion 3 may be in communicative connection with an off-chip dynamic random access memory (DRAM) and the processing portion 2, respectively.

According to a preferred mode, the reading portion 1 is for reading a neighbor list of each of vertices in the DRAM and conducting sampling. Further, the reading portion 1 writes the sampling data of every vertex back into the DRAM, and records the traversal order of each of the vertices during sampling. After sampling, the reading portion 1 transmits the recorded vertex traversal order to the processing portion 2.

According to a preferred mode, the processing portion 2 is for: in response to the vertex traversal orders received from the reading portion 1, reading the sampling data of these vertices from the DRAM according to the graininess of the blocks. Further, the processing portion 2 reads the vector data of the sampled neighbors from the DRAM, and computes the distances between the sampled neighbors of every vertex. After the computing is finished, the processing portion 2 transmits the computed results to the updating portion 3.

According to a preferred mode, the updating portion 3 is configured to: in response to the computed distance results received from the processing portion 2, read the neighbor list of two of the neighbors to which each said distance value corresponds from the DRAM, and update the neighbor lists of the two vertices before writing them back to the DRAM.

According to a preferred mode, referring to FIG. 2, the reading portion 1 may be composed of one or more reading modules 4. The reading module 4 may be used to process vertex data in a CHANNEL of the DRAM.

According to a preferred mode, referring to FIG. 2, the reading module 4 may comprise a neighbor reading sub-module 5 and a neighbor sampling sub-module 6. Specifically, the neighbor reading sub-module 5 may be used to generate addresses and read the neighbor list of each of the vertices from the DRAM. The neighbor sampling sub-module 6 may be used to receive the neighbor list of each of the vertices in the DRAM and conduct sampling. Particularly, during sampling, the neighbor sampling sub-module 6 only samples some neighbor vertices for subsequent computing.

According to a preferred mode, during sampling, the neighbor sampling sub-module 6 maintains a reverse neighbor list of every vertex, and at the end of sampling, merges the sampling list and the reverse neighbor list of every vertex. At last, the neighbor sampling sub-module 6 further records the traversal order of every vertex, and stores the result on the chip.

According to a preferred mode, referring to FIG. 2, the processing portion 2 may comprise a pre-reading module 7 and a distance computing module 8 that communicate with each other. Specifically, the pre-reading module 7 may be used to read the sampling data of all vertices from the DRAM, and read the vector data of the sampled neighbors, before caching these data onto the chip. The distance computing module 8 may be used to compute the distance between each two sampled neighbors according to the sampling data and the vector data of the vertices received from the pre-reading module 7.

According to a preferred mode, after the pre-reading module 7 reads some of the vector data, the distance computing module 8 can start to perform the relevant computing tasks. Further, when the vector data of a block have all been read, the pre-reading module 7 can start to read the data of the next block immediately.

According to a preferred mode, referring to FIG. 2, the pre-reading module 7 may be composed of one or more pre-reading sub-modules 9. The pre-reading sub-module 9 may be used to process the vertex data in a CHANNEL of the DRAM.

According to a preferred mode, referring to FIG. 2, the pre-reading sub-module 9 may comprise a neighbor reading unit 10 and a neighbor sampling unit 11. Specifically, the neighbor reading unit 10 is capable of generating access addresses according to the recorded IDs of the vertices in the block, and reading the sampled neighbors of these vertices from the DRAM. The neighbor sampling unit 11 is capable of generating access addresses based on the IDs of the sampled neighbors obtained from the neighbor reading unit 10, and reading the vector data of the sampled neighbors from the DRAM.

According to a preferred mode, referring to FIG. 2, the distance computing module 8 may be composed of one or more distance computing sub-modules 12. The distance computing sub-module 12 may be used to compute the distances between each two sampled neighbors of each of the vertices.

According to a preferred mode, referring to FIG. 2, the distance computing sub-module 12 may comprise a vector caching unit 13 and a computing unit 14. Further, the vector caching unit 13 is capable of acquiring the vector data of the sampled neighbors of each of the vertices from the pre-reading module 7. The computing unit 14 may be used to compute the distance between vector data of each two sampled neighbors cached in the vector caching unit 13, and send the computed results to the updating portion 3. Specifically, in the process of computing the distance between the sampled neighbors of each of the vertices according to the vector data of the sampled neighbors, the computing unit 14 records the current maximum distance of the neighbors of every vertex, and when the computed intermediate result excesses the maximum distance, the relevant computing task is early terminated, and the computed result is discarded directly.

According to a preferred mode, referring to FIG. 2, the updating portion 3 may be composed of one or more updating modules 15. The updating module 15 may be used to process vertex data in a CHANNEL of the DRAM.

According to a preferred mode, referring to FIG. 2, the updating module 15 may comprise a neighbor loading sub-module 16 and a neighbor merging sub-module 17. Further, the neighbor loading sub-module 16 may be used to generate addresses and reading the neighbor list of each of the vertices from the DRAM. The neighbor merging sub-module 17 can update the neighbor lists of the two vertices according to the distance value between the sampled neighbors of each of the vertices as obtained by the processing portion 2.

Specifically, the neighbor merging sub-module 17 can receive the distance values obtained by the distance computing sub-module 12, and read a neighbor list of the two vertices to which each said distance value corresponds from the DRAM. Further, the neighbor merging sub-module 17 compares the distance value with the distance values of the existing neighbors of each of the vertices, so as to determine whether to add new neighbors into the neighbor lists of the relevant vertices. The updated vertex lists are written back into the DRAM.

According to a preferred mode, for each pair of vertices for which the distance value is computed, the algorithm in the system updates the neighbor lists of the two vertices, bringing about a large amount of off-chip memory reading and writing. For reducing these overheads, the system executes neighborhood updating according to graininess of the block. Specifically, the system caches the temporary neighbor lists of all the vertices to be updated in the block. When computing of a block finishes, the system loads the neighbor lists of these vertices, and merges the same with the temporary neighbor lists. Further, after updating in the block finishes, the new neighbor lists of these vertices are written back into the DRAM.

According to a preferred mode, the system stores the data of all vertices in different areas. All the data of the vertex i (i.e., vector data, neighbor list data, and sampling list data) are stored in the j^{th} CHANNEL of the DRAM:

$$j = \frac{i}{c hannel\_num} .$$

Particularly, since every vertex has the same vector dimension, the same number of neighbors and sampling lists of the same size, a fixed storage area is assigned to data of each type in every CHANNEL of the DRAM, and the starting addresses of these areas are stored on the chip. For example, the neighbor list data of the vertex i are stored in the j^{th} channel of the DRAM, and the index address of the neighbor list data is as below (where k is the number of neighbors):

$$NEIGHBOR\_OFFSET + j * ( k * \frac{32}{8} ) .$$

In an optional mode, the disclosed system uses an FPGA accelerator modeled U250 from Xilinx. The accelerator has a 64 GB DRAM integrated therein.

Further, in the present disclosure, the data to be processed by the processor are original vector data. Each vector is a vertex. The purpose of the disclosed system is to find out the k vectors nearest to each vector through computing. The vector data are first transmitted from the DRAM of the CPU to the DRAM of the accelerator through the PICE interface. After processing, the constructed graph data will be sent to the CPU.

Specifically, the disclosed system uses a CPU modeled Intel E5-2680v4, and is equipped with a 128 GB DRAM and a 1 TB SSD.

### Embodiment 3

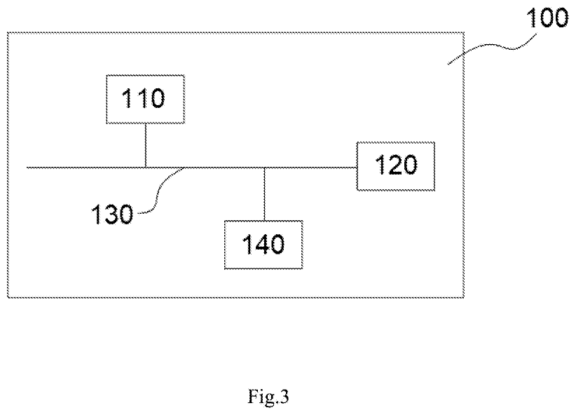

According to a preferred mode, the present embodiment provides an electronic device 100 applicable to the FPGA-based method for accelerating graph construction of Embodiment 1. Specifically, referring to FIG. 3, the electronic device 100 may comprise: one or more processors 110, a memory 120, and communication bus 130 at least for connecting the processors 110 and the memory 120.

According to a preferred mode, the memory 120 is configured to store a computer system readable medium. The computer system readable medium has the various function of the embodiments of the present disclosure.

According to a preferred mode, the processor 110 is configured to execute a computer system readable medium stored in the memory 120 for implementing various functional applications and data processing, particularly the FPGA-based method for accelerating graph construction in Embodiment 1. The method at least comprises: sampling neighborhoods of all vertices, and recording a traversal order for all of the vertices during sampling; according to a vertex traversal order, grouping all vertices into plural block of a fixed size and processing them by granularity of blocks, so as to at least obtain the distance between the sampled neighbors of each of the vertices; and according to the distance between two vertices, updating the neighborhoods of the two relevant vertices.

According to a preferred mode, the processor 110 includes but is not limited to a central processing unit (CPU), a micro-processor unit (MPU), a micro control unit (MCU), and a system-on-chip (SOC).

According to a preferred mode, the memory 120 includes but is not limited to a volatile memory (e.g., a DRAM or an SRAM) and a non-volatile memory (e.g., a flash storage, an optical disk, a floppy disk, and a mechanical hard drive).

According to a preferred mode, the communication bus 130 includes but is not limited to an industry standard architecture bus, a micro-channel architecture bus, an enhanced ISA bus, video electronics standards association local bus, and a peripheral component interconnect bus.

According to a preferred mode, as shown in FIG. 3, the electronic device 100 may further comprise at least one communication interface 140. Specifically, the electronic device 100 may be in communicative connection with at least one external device through the communication interface 140. Alternatively, the electronic device 100 may be in communicative connection with at least one external network through a network adapter. The network adapter is in communicative connection with the communication bus 130.

Further, the present disclosure further provides a storage medium that contains computer-executable instructions. The computer-executable instructions when executed by a computer processor may be used to execute the FPGA-based method for accelerating graph construction as described in Embodiment 1.

According to a preferred mode, the computer storage medium of the present disclosure may be any combination of one or more computer-readable media. Each of the computer-readable media may be a computer-readable signal medium or a computer-readable storage medium. The computer-readable storage medium includes but is not limited to an electric, magnetic, optical, electromagnetic, infrared or semiconductor system, apparatus or device, or any combination thereof.

According to a preferred mode, more specific examples of the computer-readable storage medium include: electric connection with one or more cables, a portable computer disk, a hard drive, a random-access memory (RAM), a read-only memory (ROM), an erasable programmable read-only memory (EPROM or a flash memory), an optical fiber, a compact disc read-only memory (CD-ROM), an optical storage device, a magnetic storage device, or any combination thereof. In the present disclosure, the computer-readable storage medium may be any tangible medium containing or storing a program. The program may be used by or with a system, an apparatus or a device for executing instructions.

According to a preferred mode, the computer-readable signals medium may include data signals propagated in a baseband or as a part of carrier waves, in which computer-readable program codes are carried. Data signals such propagated may be in various forms, including but not limited to electromagnetic signals, optical signals, or any suitable combination thereof. The computer-readable signal medium may alternatively be any computer-readable medium other than a computer-readable storage medium. The computer-readable medium is able to send, propagate or transmit a program to be used by or with a system, an apparatus or a device for executing instructions.

According to a preferred mode, the program codes contained in the computer-readable medium may be transmitted using any suitable medium, including but not limited to wireless means, power cords, optical cables, or RF, or any combination thereof.

According to a preferred mode, computer program codes used to execute the operation as described in the embodiments of the present disclosure may be written using one or more programming languages or a combination thereof. Suitable programming languages include object-oriented programming languages, such as Python, Java, Smalltalk, and C++, and include conventional procedural programming languages, such as “C” language or similar programming language. The program codes may be completely executed in a user computer, partially executed in a user computer, executed as an independent software pack, partially executed in a user computer while partially executed in a remote computer, or completely executed in a remote computer or a server. In a case where a remote computer is involved, the remote computer may be connected to the user computer through a network of any type, such as a local area network (LAN) or a wide area network (WAN). Alternatively, it may be connected to an external computer (such as connected through the Internet by an Internet service provider).

It is to be noted that the particular embodiments described previously are exemplary. People skilled in the art, with inspiration from the disclosure of the present disclosure, would be able to devise various solutions, and all these solutions shall be regarded as a part of the disclosure and protected by the present disclosure. Further, people skilled in the art would appreciate that the descriptions and accompanying drawings provided herein are illustrative and form no limitation to any of the appended claims. The scope of the present disclosure is defined by the appended claims and equivalents thereof. The disclosure provided herein contains various inventive concepts, such of those described in sections led by terms or phrases like “preferably”, “according to one preferred mode” or “optionally”. Each of the inventive concepts represents an independent conception and the applicant reserves the right to file one or more divisional applications therefor.

What is claimed is:

1. An FPGA-based method for accelerating graph construction, comprising:
Step 1: sampling neighborhood of each vertex in stored data, respectively, and recording a traversal order for all of the vertices;
Step 2: according to the vertex traversal order, grouping the vertices into a plurality of blocks and processing them by block granularity, so as to at least obtain distance values between each two sampled neighbors of each of the vertices in each of the blocks;
Step 3: according to the distance values regarding the sampled neighbors of each of the vertices, updating the neighborhoods of the two relevant vertices; and
Step 4: processing all of the blocks, starting a new iteration from Step 1, until a graph constructed therefrom has a satisfying precision or a predetermined limit of the number of iterations has been reached.

2. The FPGA-based method of claim 1, wherein the Step 1 comprises steps of:
Step 11: sampling the neighborhood of each of the vertices, adding IDs of some of the neighbors of each of the vertices into a sampling list, adding a ID of each of the vertices into a reverse list of the sampled neighbors, and recording the traversal order for all of the vertices during sampling; and
Step 12: repeating the Step 11, until all of the vertices have been processed, and merging the sampling list and the reverse list of each of the vertices.

3. The FPGA-based method of claim 2, wherein the Step 2 comprises steps of:
Step 21: loading the IDs of the sampled neighbors of all of the vertices in one of the blocks and feature vectors corresponding to these sampled neighbors; and
Step 22: computing data loaded in the Step 21 to acquire the distance values regarding the sampled neighbors of each of the vertices.

4. The FPGA-based method of claim 3, wherein the Step 3 comprises steps of:
Step 31: reading a neighbor list of the two vertices to which each said distance value corresponds; and
Step 32: comparing each said distance value with distance values of existing neighbors of each vertex, so as to determine whether to add new neighbors to the neighbor list of the relevant vertex.

5. The FPGA-based method of claim 4, wherein the Step 21 comprises steps of:
Step 211: according to the recorded IDs of all of the vertices in each of the blocks, reading data of the sampling lists of these vertices; and
Step 212: according to the read data of the sampling lists of the vertices, reading the feature vectors of the sampled neighbors.

6. The FPGA-based method of claim 5, wherein the Step 22 comprises steps of:
Step 221: according to loaded data of the sampled neighbors of each of the vertices and the feature vectors of these sampled neighbors, generating computing tasks; and
Step 222: processing the generated computing tasks, and recording a maximum distance value regarding each of the neighbors during computing, wherein when a computed intermediate result exceeds the maximum distance value, the relevant computing task is early terminated, and the intermediate result is discarded directly without participating in subsequent steps.

7. The FPGA-based method of claim 6, wherein all of the vertices are processed in the DRAM by granularity of blocks, all the required vector data are prefetched to the chip from the blocks, the work load for accessing off-chip memories with high latency can be decreased.

8. The FPGA-based method of claim 7, wherein once the neighbor data of the vertices have been loaded, these data are immediately moved to an idle processing module for processing, without waiting complete loading of all data of all neighborhoods in the blocks, so as to optimize efficiency throughout the dataflow.

9. The FPGA-based method of claim 8, wherein after each dimension of the vertex pair data are processed, the computed intermediate result is compared with the maximum value, if the computing for the present vertex pair is recognized as unnecessary computing, the computing is directly ended.

10. The FPGA-based method of claim 9, wherein in the process of computing the distance between the sampled neighbors of each of the vertices based on the vector data of the sampled neighbors, the current maximum distance of the neighbors of every vertex is recorded.

11. An FPGA-based system for accelerating graph construction, comprising a reading portion, a processing portion and an updating portion, which three are configured to communicate with a DRAM, wherein
the reading portion is used for reading a neighbor list of each of vertices in the DRAM and conducting sampling, wherein sampled data of each of the vertices are written back into the DRAM, and a traversal order of each of the vertices is recorded;
the processing portion is capable of, in response to the received vertex traversal order, grouping the vertices into a plurality of blocks and processing them by block granularity, so as to at least obtain distance values between each two sampled neighbors of each of the vertices in each of the blocks; and
the updating portion is capable of, in response to the received distance values regarding the sampled neighbors of each of the vertices, reading the neighbor list of the two neighbors to which each said distance value corresponds from the DRAM, updating the neighbor lists of the two vertices, and writing them back into the DRAM.

12. The FPGA-based system of claim 11, wherein the reading portion comprises one or more reading modules for processing vertex data in a CHANNEL of the DRAM, and the reading module comprises:
a neighbor reading sub-module, for generating addresses and reading the neighbor list of each of the vertices from the DRAM; and
a neighbor sampling sub-module, for receiving the neighbor list of each of the vertices in the DRAM, conducting sampling, and recording the traversal order of the vertices, wherein the neighbor sampling sub-module only samples some of the neighbors used in computing, and maintains a reverse neighbor list for each of the vertices, so as to merge the sampling list and the reverse neighbor list of each of the vertices when sampling finishes.

13. The FPGA-based system of claim 12, wherein the processing portion comprises:
a pre-reading module, for reading sampling data of all of vertices in the DRAM and vector data of the sampled neighbors, and on-chip caching the data; and
a distance computing module, capable of computing a distance value between each two of the sampled neighbors according to the sampling data and the vector data of all of the vertices from the pre-reading module.

14. The FPGA-based system of claim 13, wherein the updating portion comprises one or more updating modules for processing vertex data in a CHANNEL of the DRAM, and the updating module comprises:
a neighbor loading sub-module, for generating addresses and reading the neighbor list of each of the vertices from the DRAM; and
a neighbor merging sub-module, for receiving the distance values computed by the distance computing sub-module, reading the neighbor list of the two neighbors to which each said distance value corresponds from the DRAM, and comparing each said distance value with distance values of existing neighbors of each vertex, so as to determine whether to add new neighbors into the neighbor lists of the relevant vertices.

15. The FPGA-based system of claim 14, wherein the system processes all of the vertices in the DRAM by granularity of blocks, since all the required vector data are prefetched to the chip from the blocks, the work load for accessing off-chip memories with high latency can be decreased.

16. The FPGA-based system of claim 15, wherein once the neighbor data of the vertices have been loaded, the system can immediately move these data to an idle processing module for processing, without waiting complete loading of all data of all neighborhoods in the blocks, so as to optimize efficiency throughout the dataflow.

17. The FPGA-based system of claim 16, wherein after processing each dimension of the vertex pair data, the processing module of the system compares the computed intermediate result with the maximum value, if the computing for the present vertex pair is recognized as unnecessary computing, the processing module directly ends the computing, and waits for subsequent processing. the intermediate result for which the computing is early terminated is not transferred to the updating module.

18. The FPGA-based system of claim 17, wherein after the pre-reading module reads some vector data, the distance computing module can start execution,
when the vector data of a block have been read, the pre-reading module can immediately start to read data of the next block, thereby hiding off-chip access delay and optimizing performance of the system.

19. The FPGA-based system of claim 18, wherein in the process of computing the distance between the sampled neighbors of each of the vertices based on the vector data of the sampled neighbors, the computing unit records the current maximum distance of the neighbors of every vertex.

20. The FPGA-based system of claim 19, wherein when the computed intermediate result exceeds the maximum intermediate distance, the relevant computing task is early terminated, and the computed result is discarded directly.
